(19) United States
(12) Patent Application Publication
(10) Pub. No.: US 2016/0233184 A1
(43) Pub. Date: Aug. 11, 2016

(54) Semiconductor Device Manufacturing Method

(71) Applicant: NITTO DENKO CORPORATION, Osaka (JP)

(72) Inventors: Hiroyuki Hanazono, Ibaraki-shi (JP); Naohide Takamoto, Ibaraki-shi (JP); Akihiro Fukui, Ibaraki-shi (JP)

(73) Assignee: Nitto Denko Corporation, Osaka (JP)

(21) Appl. No.: 15/024,552

(22) PCT Filed: Sep. 19, 2014
(86) PCT No.: PCT/JP2014/074899

§ 371 Date: Mar. 24, 2016

(30) Foreign Application Priority Data
Sep. 25, 2013 (JP) 2013-198644

(51) Int. Cl. H01L 23/00

(52) U.S. Cl. CPC H01L 24/11; H01L 2224/11019; H01L 2224/11502; H01L 2224/11515; H01L 2224/1155

(57) ABSTRACT

A method for manufacturing a semiconductor includes: a Step A of preparing a chip with sheet-shaped resin composition in which a sheet-shaped resin composition is pasted onto a semiconductor chip, a Step B of preparing an adherend, a Step C of pasting the chip with sheet-shaped resin composition onto the adherend so that the sheet-shaped resin composition serves as a pasting surface, a Step D of heating the sheet-shaped resin composition to semi-cure the sheet-shaped resin composition after the Step C, and a Step E of heating the sheet-shaped resin composition at a higher temperature than in the Step D to cure the sheet-shaped resin composition after the Step D.

### TECHNICAL FIELD

The present invention relates to a method for manufacturing a semiconductor device.

### BACKGROUND ART

In recent years, there has been a rapidly increasing demand for high density mounting due to reduction of the size and the thickness of electronics. For this reason, a surface mounting semiconductor package that is suitable for high density mounting has become commonplace in place of a conventional pin inserting semiconductor package. In this surface mounting semiconductor package, the lead is directly soldered onto a printed board, etc. The entire package is heated to be mounted with a heating method such as infrared reflow, vapor phase reflow, or solder dip.

In order to protect the surface of a semiconductor element and to secure the connection reliability between the semiconductor element and the substrate, a space between the semiconductor element and the substrate is filled with a sealing resin after surface mounting. The process of filling a space between the semiconductor element and the substrate is also called underfill. Liquid sealing resin is widely used as the sealing resin for underfill. However, it is difficult to adjust the injection position and the injection amount of liquid sealing resin. Accordingly, techniques have been proposed which involve filling the space between the semiconductor element and the substrate using a sheet-shaped resin composition (for example, refer to Patent Document 1).

Patent Document 1 discloses the steps of attaching a wafer to a sheet-shaped resin composition, dicing the wafer with the sheet-shaped resin composition attached to forma chip, and thermally curing the sheet-shaped resin composition to seal the interface between the chip and the substrate while mounting the surface of the sheet-shaped resin composition onto the substrate to obtain an electric connection between the substrate and the chip.

### PRIOR ART DOCUMENTS

### Patent Documents

Patent Document 1: Patent No. 4438973

### SUMMARY OF THE INVENTION

### Problems To Be Solved By The Invention

Electric connection between the substrate and the chip can be established by electrically connecting an electrode formed on the substrate to a bump formed on the chip. When the sheet-shaped resin composition and the substrate are pasted together, air bubbles (voids) may be caught in an uneven portion caused by the electrodes formed on the substrate. The voids may also be caught in an uneven portion caused by the bumps formed on the wafer when the sheet-shaped resin composition and the substrate are pasted together.

The inventors of the present invention keenly examined a method for manufacturing a semiconductor device using the sheet-shaped resin composition. As a result, it was found that the voids that were caught in the uneven portion by heating expand, and the sheet-shaped resin composition cures with expanded voids because the electric connection between the substrate and the chip is established as the sheet-shaped resin composition is cured by heating once in the conventional method for manufacturing a semiconductor. For this reason, it was found that large voids exist in the sheet-shaped resin composition. Because these large voids cause various types of problems such as deterioration of the reliability, it is desirable to suppress the generation of large voids.

In general, voids are easily caught in an uneven portion whether the unevenness is caused by an electrode or a bump. Therefore, it is desirable not to allow the air bubbles to expand even if they are caught in the uneven portion when the sheet-shaped resin composition is pasted onto various types of adherends.

The present invention has been made in consideration of the above-described problem, and an object thereof is to provide a method for manufacturing a semiconductor device that enables suppression of the expansion of voids even if the voids are caught between a sheet-shaped resin composition and an adherend.

### Means For Solving The Problems

The inventors of the present invention have found that the above-described problem can be solved by adopting the following configuration, and have completed the present invention.

Accordingly, the present invention is a method for manufacturing a semiconductor device including: a Step A of preparing a chip with sheet-shaped resin composition in which a sheet-shaped resin composition is pasted onto a semiconductor chip, a Step B of preparing an adherend, a Step C of pasting the chip with sheet-shaped resin composition onto the adherend so that the sheet-shaped resin composition serves as a pasting surface, a Step D of heating the sheet-shaped resin composition to semi-cure the sheet-shaped resin composition after the Step C, and a Step E of heating the sheet-shaped resin composition at a higher temperature than in the Step D to cure the sheet-shaped resin composition after the Step D.

In the method for manufacturing a semiconductor device according to the present invention, the sheet-shaped resin composition is semi-cured by being heated in a condition in which the chip with sheet-shaped resin composition is pasted onto the adherend so that the sheet-shaped resin composition serves as a pasting surface (Step D). Therefore, the viscosity of the sheet-shaped resin composition increases before partial curing. Then, the sheet-shaped resin composition is cured by being heated at a higher temperature than that in the Step D (Step E). Because the sheet-shaped resin composition is already semi-cured at a stage of the Step E, the expansion of voids is suppressed even if the voids are caught between the sheet-shaped resin composition and the adherend. Therefore, the generation of large voids that cause various types of problems can be suppressed.

The sheet-shaped resin composition in the above-described configuration preferably has a thermal curing rate of 10% or more after heating at 200° C. for 10 seconds.

If the sheet-shaped resin composition has a thermal curing rate of 10% or more after heating at 200° C. for 10 seconds, the viscosity of the sheet-shaped resin composition after the Step D increases to some extent. As a result, the expansion of voids can be further suppressed.

The thermal curing rate is a value calculated from reaction heat obtained from a differential scanning calorimeter (DSC) by considering a condition before heating as 0%, and a condition in which the sheet-shaped resin composition is completely cured as 100%. This is explained later more specifically.

The adherend of the above-described configuration may have an unevenness of 3 μm to 100 μm on the surface onto which the sheet-shaped resin composition is pasted.

If the adherend has unevenness of 3 μm to 100 μm, air bubbles are easily caught between the adherend and the sheet-shaped resin composition. However, as described above, the viscosity of the sheet-shaped resin composition is increased after the Step D. Therefore, even if the adherend having the unevenness of 3 μm to 100 μm is used, the expansion of voids is suppressed so that the generation of large voids that cause various types of problems can be suppressed.

The semiconductor chip of the above-described configuration may have an unevenness of 3 μm to 100 μm on the surface onto which the sheet-shaped resin composition is pasted.

If the semiconductor chip has an unevenness of 3 μm to 100 μm, air bubbles are easily caught between the adherend and the sheet-shaped resin composition. However, as described above, the viscosity of the sheet-shaped resin composition is increased after the Step D. Therefore, even if the semiconductor chip having the unevenness of 3 μm to 100 μm is used, the expansion of voids is suppressed, so that the generation of large voids that cause various types of problems can be suppressed.

### Effect Of The Invention

According to the present invention, it is possible to provide a method for manufacturing a semiconductor device that enables suppression of the expansion of voids even if the voids are caught between a sheet-shaped resin composition and an adherend.

### BRIEF DESCRIPTION OF THE DRAWINGS

FIG. 1 is a schematic cross sectional view for explaining the method for manufacturing a semiconductor device according to one embodiment of the present invention.

FIG. 2 is a schematic cross sectional view for explaining the method for manufacturing a semiconductor device according to one embodiment of the present invention.

FIG. 3 is a schematic cross sectional view for explaining the method for manufacturing a semiconductor device according to one embodiment of the present invention.

FIG. 4 is a schematic cross sectional view for explaining the method for manufacturing a semiconductor device according to one embodiment of the present invention.

FIG. 5 is a schematic cross sectional view for explaining one example of a method for preparing a chip with sheet-shaped resin composition.

FIG. 6 is a schematic cross sectional view for explaining one example of a method for preparing a chip with sheet-shaped resin composition.

FIG. 7 is a schematic cross sectional view for explaining one example of a method for preparing a chip with sheet-shaped resin composition.

FIG. 8 is a schematic cross sectional view for explaining one example of a method for preparing a chip with sheet-shaped resin composition.

FIG. 9 is a schematic cross sectional view for explaining one example of a method for preparing a chip with sheet-shaped resin composition.

FIG. 10 is a schematic cross sectional view for explaining one example of a method for preparing a chip with sheet-shaped resin composition.

FIG. 11 is a schematic cross sectional view for explaining one example of a method for preparing a chip with sheet-shaped resin composition.

### MODE FOR CARRYING OUT THE INVENTION

The embodiment of the present invention is explained below with reference to the drawings.

The method for manufacturing a semiconductor device according to the present invention includes: the Step A of preparing a chip with sheet-shaped resin composition in which a sheet-shaped resin composition is pasted onto a semiconductor chip, the Step B of preparing an adherend, the Step C of pasting the chip with sheet-shaped resin composition onto the adherend so that the sheet-shaped resin composition serves as a pasting surface, the Step D of heating the sheet-shaped resin composition to semi-cure the sheet-shaped resin composition after the Step C, and the Step E of heating the sheet-shaped resin composition at a higher temperature than in the Step D to cure the sheet-shaped resin composition after the Step D.

First, one embodiment according to the present invention is explained below in which bumps are formed on a semiconductor chip and electrodes are formed on a substrate as an adherend.

Accordingly, the method for manufacturing a semiconductor device according to the present embodiment at least includes: the Step A of preparing a chip with sheet-shaped resin composition in which a sheet-shaped resin composition is pasted onto a bump formation surface of a semiconductor chip, the Step B of preparing a substrate for mounting on which electrodes are formed, the Step C of pasting the chip with sheet-shaped resin composition onto the substrate for mounting so that the sheet-shaped resin composition serves as a pasting surface with the bumps formed on the semiconductor chip facing toward the electrodes formed on the substrate for mounting, the Step D of heating the sheet-shaped resin composition to semi-cure the sheet-shaped resin composition after the Step C, and the Step E of heating the sheet-shaped resin composition at a higher temperature than in the Step D to cure the sheet-shaped resin composition after the Step D while bonding the bump and the electrode.

[Step of Preparing Chip with Sheet-Shaped Resin Composition]

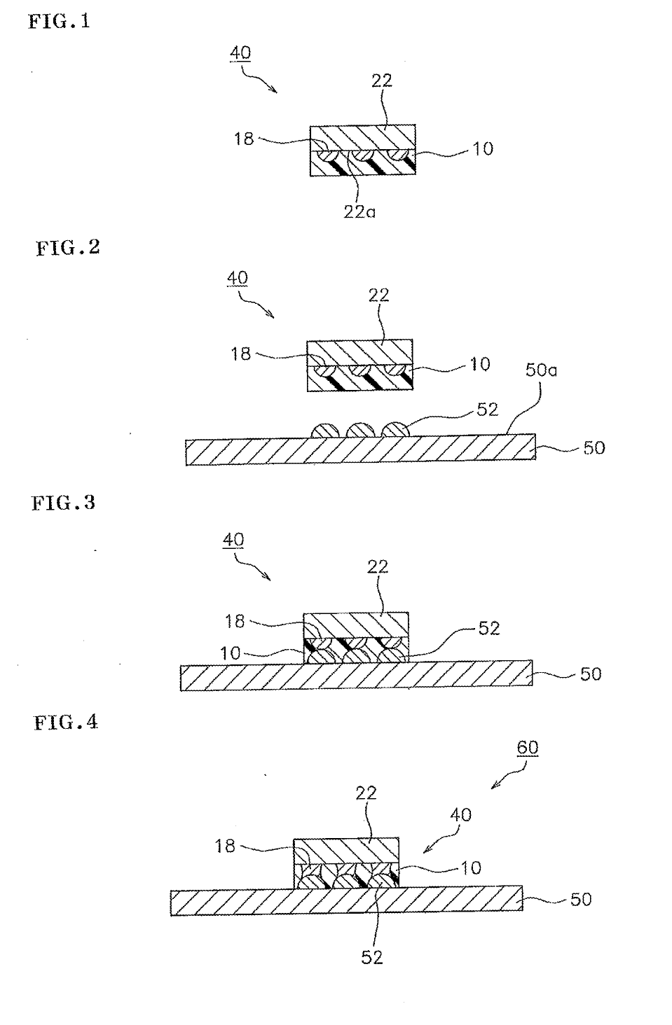

FIGS. 1 to 4 are schematic cross sectional views for explaining a method for manufacturing a semiconductor device according to one embodiment of the present invention.

In the method for manufacturing a semiconductor device according to the present embodiment, as shown in FIG. 1, a chip 40 with sheet-shaped resin composition is first prepared (Step A). A specific method for preparing the chip 40 with sheet-shaped resin composition is explained later by referring to FIGS. 5 to 11.

The chip 40 with sheet-shaped resin composition has a semiconductor chip 22 on which bumps 18 are formed and a sheet-shaped resin composition 10 that is pasted onto a bump formation surface 22a of the semiconductor chip 22. In the chip 40 with sheet-shaped resin composition, the bumps 18 are embedded in the sheet-shaped resin composition 10 and the bump formation surface 22a of the semiconductor chip 22 is pasted onto the sheet-shaped resin composition 10.

(Sheet-Shaped Resin Composition)

The sheet-shaped resin composition 10 has a function of sealing a space between the semiconductor chip 22 and a substrate 50 for mounting when mounting the semiconductor chip 22 to the substrate 50 for mounting (refer to FIG. 2).

The sheet-shaped resin composition 10 preferably has a thermal curing rate of 10% or more after heating at 200° C. for 10 seconds, and more preferably, 13% or more. If the sheet-shaped resin composition 10 has a thermal curing rate of 10% or more after heating at 200° C. for 10 seconds, the viscosity of the sheet-shaped resin composition 10 after the Step D increases to some extent. As a result, the expansion of voids can be further suppressed.

The thermal curing rate is obtained by measuring the heating value using a differential scanning calorimeter (DSC). Specifically, a thermally uncured sheet-shaped resin composition is produced, and the heating value (reaction heat of an uncured sample) is measured when the temperature is increased from −10° C. to 350° C. (a temperature at which the reaction of the uncured sample is assumed to be completed) in a condition of a rising temperature speed of 10° C/min. In addition, a sample is produced in which the sheet-shaped resin composition before thermal curing is heated at 200° C. for 10 seconds.

Next, the heating value of the sample heated at 200° C. for 10 seconds (reaction heat of the uncured sample heated at 200° C. for 10 seconds) is measured when the temperature is increased from −10° C. to 350° C. (a temperature at which the reaction of the uncured sample is assumed to be completed) in a condition of a rising temperature speed of 10° C/min. Then, the thermal curing rate is obtained from the following formula (3). The heating value is obtained using an area surrounded by the peak and the straight line connecting two temperature points that are the rising temperature of the exothermic peak measured with a differential scanning calorimeter and the reaction completing temperature.

Thermal curing rate=[{(Reaction heat of uncured sample)−(Reaction heat of sample heated at 200° C. for 10 seconds)}/(Reaction heat of uncured sample)]×100 (%) tm Formula (3)

The sheet-shaped resin composition 10 preferably has a minimum melt viscosity of 100 Pa·s to 5,000 Pa·s at less than 200° C., more preferably 300 Pa·s to 4,000 Pa·s, and further preferably 500 Pa·s to 2,000 Pa·s. If the minimum melt viscosity of the sheet-shaped resin composition 10 is 100 Pa·s to 5,000 Pa·s at less than 200° C., the bump 18 formed on the semiconductor chip 22 and an electrode 52 formed on the substrate 50 for mounting can be made to face each other while easily embedding them into the sheet-shaped resin composition 10 in the Step C.

The minimum melt viscosity of the sheet-shaped resin composition 10 at less than 200° C. is a minimum melt viscosity at less than 200° C. before curing.

The minimum melt viscosity of the sheet-shaped resin composition 10 at less than 200° C. can be controlled by selecting a constituent material of the sheet-shaped resin composition 10. Especially, it can be controlled by selecting a thermoplastic resin. Specifically, a small minimum melt viscosity at less than 200° C. can be obtained if a thermoplastic resin having low molecular weight is used, for example, and a large minimum melt viscosity at less than 200° C. can be obtained if a thermoplastic resin having high molecular weight is used, for example.

An example of the sheet-shaped resin composition 10 is a resin composition made from a thermoplastic resin and a thermosetting resin. Further, a thermosetting resin can be used alone as the sheet-shaped resin composition 10.

Examples of the thermoplastic resin include natural rubber, butyl rubber, isoprene rubber, chloroprene rubber, ethylene/vinyl acetate copolymer, ethylene/acrylic acid copolymer, ethylene/acrylic ester copolymer, polybutadiene resin, polycarbonate resin, thermoplastic polyimide resin, polyamide resins such as 6-nylon and 6,6-nylon, phenoxy resin, acrylic resin, saturated polyester resins such as PET and PBT, polyamideimide resin, and fluorine-contained resin. These thermoplastic resins may be used alone or in combination of two or more thereof. Of these thermoplastic resins, acrylic resin is particularly preferable since the resin contains ionic impurities in only small amounts and has a high heat resistance so as to make it possible to ensure the reliability of the semiconductor chip.

The acrylic resin is not limited to any especial kind, and may be, for example, a polymer comprising, as a component or components, one or more esters of acrylic acid or methacrylic acid having a linear or branched alkyl group having 30 or fewer carbon atoms, in particular, 4 to 18 carbon atoms. Examples of the alkyl group include methyl, ethyl, propyl, isopropyl, n-butyl, t-butyl, isobutyl, amyl, isoamyl, hexyl, heptyl, cyclohexyl, 2-ethylhexyl, octyl, isooctyl, nonyl, isononyl, decyl, isodecyl, undecyl, lauryl, tridecyl, tetradecyl, stearyl, octadecyl, and dodecyl groups.

A different monomer which constitutes the above-mentioned polymer is not limited to any especial kind, and examples thereof include carboxyl-containing monomers such as acrylic acid, methacrylic acid, carboxyethyl acrylate, carboxypentyl acrylate, itaconic acid, maleic acid, fumaric acid, and crotonic acid; acid anhydride monomers such as maleic anhydride and itaconic anhydride; hydroxyl-containing monomers such as 2-hydroxyethyl (meth) acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl) methylacrylate; monomers which contain a sulfonic acid group, such as styrenesulfonic acid, allylsulfonic acid, 2-(meth)acrylamide-2-methylpropanesulfonic acid, (meth)acrylamidepropane sulfonic acid, sulfopropyl (meth)acrylate, and (meth)acryloyloxynaphthalenesulfonic acid; and monomers which contain a phosphoric acid group, such as 2-hydroxyethylacryloyl phosphate.

The content of the thermoplastic resin is preferably 3% by weight or more, and more preferably 4% by weight or more of the entire amount of the sheet-shaped resin composition 10. If the content of the thermoplastic resin is 4% by weight or more, good flexibility can be obtained. On the other hand, the content of the thermoplastic resin in the resin component is preferably 15% by weight or less, more preferably 12% by weight or less, and further preferably 8% by weight or less. If the content of the thermoplastic resin is 8% by weight or less, good thermal reliability can be obtained.

Among the thermoplastic resins, an acrylic resin is preferable in order to obtain a low viscosity of the sheet-shaped resin composition 10 before partial curing.

Examples of the above-mentioned thermosetting resin include phenol resin, amino resin, unsaturated polyester resin, epoxy resin, polyurethane resin, silicone resin, and thermosetting polyimide resin. These resins may be used alone or in combination of two or more thereof. Particularly preferable is epoxy resin, which contains ionic impurities which corrode semiconductor elements only a small amount. As the curing agent of the epoxy resin, phenol resin is preferable.

The epoxy resin may be any epoxy resin that is ordinarily used as an adhesive composition. Examples thereof include bifunctional or polyfunctional epoxy resins such as bisphenol A type, bisphenol F type, bisphenol S type, brominated bisphenol A type, hydrogenated bisphenol A type, bisphenol AF type, biphenyl type, naphthalene type, fluorene type, phenol Novolak type, orthocresol Novolak type, tris-hydroxyphenylmethane type, and tetraphenylolethane type epoxy resins; hydantoin type epoxy resins; tris-glycicylisocyanurate type epoxy resins; and glycidylamine type epoxy resins. These may be used alone or in combination of two or more thereof. Among these epoxy resins, particularly preferable are Novolak type epoxy resin, biphenyl type epoxy resin, tris-hydroxyphenylmethane type epoxy resin, and tetraphenylolethane type epoxy resin, since these epoxy resins are rich in reactivity with phenol resin as an agent for curing the epoxy resin and are superior in heat resistance and so on.

The phenol resin is a resin acting as a curing agent for the epoxy resin. Examples thereof include Novolak type phenol resins such as phenol Novolak resin, phenol aralkyl resin, cresol Novolak resin, tert-butylphenol Novolak resin and nonylphenol Novolak resin; resol type phenol resins; and polyoxystyrenes such as poly (p-oxystyrene). These may be used alone or in combination of two or more thereof. Among these phenol resins, phenol Novolak resin and phenol aralkyl resin are particularly preferable, since the sealing reliability can be improved.

Regarding the blend ratio between the epoxy resin and the phenol resin, for example, the phenol resin is blended with the epoxy resin in such a manner that the hydroxyl groups in the phenol resin is preferably from 0.5 to 2.0 equivalents, more preferably from 0.8 to 1.2 equivalents per equivalent of the epoxy groups in the epoxy resin component. If the blend ratio between the two is out of the range, curing reaction therebetween does not advance sufficiently so that properties of the cured epoxy resin easily deteriorate.

The content of the thermosetting resin is preferably 10% by weight or more, more preferably 12% by weight or more, and further preferably 15% by weight or more of the entire amount of the sheet-shaped resin composition 10. If the content of the thermosetting resin is 10% by weight or more, good flexibility can be obtained. On the other hand, the content of the thermosetting resin in the resin component is preferably 30% by weight or less, more preferably 25% by weight or less, and further preferably 20% by weight or less. If the content of the thermosetting resin is 20% by weight or less, tackiness of the sheet can be suppressed and handleability of the sheet improves.

The thermal curing-accelerating catalyst of the epoxy resin and the phenol resin is not particularly limited, and a known thermal curing-accelerating catalyst can be appropriately selected and used. The thermal curing-accelerating catalyst may be used either alone or in combination of two or more types. Examples of the thermal curing-accelerating catalyst include an amine based curing accelerator, a phosphor based curing accelerator, an imidazole based curing accelerator, a boron based curing accelerator, and a phosphor-boron based curing accelerator.

The content of the thermal curing-accelerating catalyst is preferably 0.7 parts by weight or more, more preferably 2.4 parts by weight or more, and further preferably 4.8 parts by weight or more to 100 parts by weight of the thermosetting resin. If the content of the thermal curing-accelerating catalyst is 4.8 parts by weight or more, the sheet-shaped resin composition 10 can be easily semi-cured in the partial curing step. The content of the thermal curing-accelerating catalyst is preferably 24 parts by weight or less. If the content of the thermal curing-accelerating catalyst is 24 parts by weight or less, preservability of the thermosetting resin can be improved.

An inorganic filler may be appropriately incorporated into the sheet-shaped resin composition 16. The incorporation of the inorganic filler makes it possible to confer electric conductance to the sheet, improve the thermal conductivity thereof, and adjust the elasticity.

Examples of the inorganic fillers include various inorganic powders made of the following: a ceramic such as silica, clay, plaster, calcium carbonate, barium sulfate, aluminum oxide, beryllium oxide, silicon carbide, or silicon nitride; a metal such as aluminum, copper, silver, gold, nickel, chromium, lead, tin, zinc, palladium or solder, or an alloy thereof; and carbon. These may be used alone or in combination of two or more thereof. Among these, silica, in particular fused silica, is preferably used.

The average particle size of the inorganic filler is preferably 0.01 to 30 μm, and more preferably 0.05 to 10 μm. In the present invention, inorganic fillers having different average particle sizes can be combined and used together. The average particle size is obtained by a laser diffraction/scattering particle size distribution analyzer (LA-910 manufactured by HORIBA, Ltd.).

The compounded amount of the inorganic filler is preferably 100 to 1400 parts by weight to 100 parts by weight of the organic resin component. It is especially preferably 230 to 900 parts by weight. When the compounded amount of the inorganic filler is 100 parts by weight or more, the heat resistance and the strength improve. When it is 1400 parts by weight or less, the fluidity can be secured. With this, a decrease of the tackiness and the embedding property can be prevented.

Other additives besides the inorganic filler can be appropriately compounded in the sheet-shaped resin composition 10 as necessary. Examples of other additives include a flame retardant, a silane coupling agent, an ion trapping agent, a pigment such as carbon black. Examples of the flame retardant include antimony trioxide, antimony pentaoxide, and brominated epoxy resin. These may be used alone or in combination of two or more thereof. Examples of the silane coupling agent include β-(3,4-epoxycyclohexyl)ethyltrimethoxysilane, γ-glycidoxypropyltrimethoxysilane, and γ-glycidoxypropylmethyldiethoxysilane. These may be used alone or in combination of two or more thereof. Examples of the ion trapping agent include hydrotalcite and bismuth hydroxide. These maybe used alone or in combination of two or more thereof. For the purpose of removing the oxide film on solder at mounting, organic acid may be added.

The thickness of the sheet-shaped resin composition 10 (a total thickness when the composition is a multilayer) is not especially limited. However, considering the strength of the resin after the resin is cured and the filling property, the thickness is preferably 5 μm or more and 500 μm or less. The thickness of the sheet-shaped resin composition 10 can be appropriately set by considering the width of the space between the chip 22 and the substrate 50 for mounting.

The sheet-shaped resin composition 10 is produced as follows, for example. First, a resin composition solution is produced that is a formation material of the sheet-shaped resin composition 10. As described above, the resin composition, the filler, other various types of additives, etc., are compounded in the resin composition solution.

Next, the resin composition solution is applied on the base separator to have a prescribed thickness to forma coating film. Then, the coating film is dried under a prescribed condition to form the sheet-shaped resin composition 10. The coating method is not especially limited. However, examples include roll coating, screen coating, and gravure coating. For the drying condition, for example, the drying temperature is 70° C. to 160° C. and the drying time is 1 minute to 5 minutes.

The thickness of the semiconductor chip 22 is not particularly limited, and examples thereof can be appropriately set within a range of 10 μm to 1,000 μm.

The height of the bump 18 formed on the semiconductor chip 22 is not particularly limited; however, it is 3 μm to 100 μm. If the height of the bump 18 is 3 μm to 100 μm, that is, the semiconductor chip 22 has an unevenness of 3 μm to 100 μm, air bubbles can be easily caught between the semiconductor chip 22 and the sheet-shaped resin composition 10. However, the viscosity of the sheet-shaped resin composition 10 is increased after the Step D. Therefore, even when the semiconductor chip 22 is used having an unevenness of 3 μm to 100 μm in which air bubbles can be easily caught, the expansion of voids is suppressed so that the generation of large voids that causes various types of problems can be suppressed.

The constituent material of the bump 18 is not particularly limited. However, solder is preferable. Examples thereof are Sn—Pb, Pb—Sn—Sb, Sn—Sb, Sn—Pb—Bi, Bi—Sn, Sn—Cu, Sn—Pb—Cu, Sn—In, Sn—Ag, Sn—Pb—Ag, and Pb—Ag solder.

[Step of Preparing Substrate for Mounting]

As shown in FIG. 2, the substrate 50 for mounting is prepared, where the electrodes 52 are formed on the surface 50a (Step B).

Various types of substrates such as a lead frame and a circuit board (a wired circuit board, etc.) can be used as the substrate 50 for mounting. The material of the substrate is not particularly limited, and examples thereof are a ceramic substrate and a plastic substrate. Examples of the ceramic substrate include an epoxy substrate, a bismaleimide triazine substrate, and a polyimide substrate.

In addition, a semiconductor wafer can be also used as the substrate 50 for mounting.

The height of the electrode 52 formed on the substrate 50 for mounting is not particularly limited; however, it is 3 μm to 100 μm. If the height of the electrode 52 is 3 μm to 100 μm, that is, the substrate 50 for mounting has an unevenness of 3 μm to 100 μm, air bubbles can be easily caught between the substrate 50 for mounting and the sheet-shaped resin composition 10. However, the viscosity of the sheet-shaped resin composition 10 is increased after the Step D. Therefore, even when the substrate 50 for mounting is used having an unevenness of 3 μm to 100 μm in which air bubbles can be easily caught, the expansion of voids is suppressed so that the generation of large voids that causes various types of problems can be suppressed.

[Step of Making Bump Formed on Semiconductor Chip Face Toward Electrodes Formed on Substrate for Mounting]

After the Steps A and B, as shown in FIG. 3, the chip 40 with sheet-shaped resin composition is pasted onto the substrate 50 for mounting so that the sheet-shaped resin composition 10 becomes a pasting surface with the bumps 18 formed on the semiconductor chip 22 facing toward the electrodes 52 formed on the substrate 50 for mounting (Step C). Specifically, the sheet-shaped resin composition 10 of the chip 40 with sheet-shaped resin composition is arranged to face toward the substrate 50 for mounting, and a pressure is applied from a side of the chip 40 with sheet-shaped resin composition using a flip-chip bonder. This makes it possible to face the bump 18 and the electrode 52 toward each other while easily embedding them into the sheet-shaped resin composition 10. The temperature at pasting is preferably 100° C. to 200° C., and more preferably 150° C. to 190° C. However, it is preferably lower than a melting point of the solder. The pressure at pasting is preferably 0.01 MPa to 10 MPa, and more preferably 0.1 MPa to 1 MPa.

If the pasting temperature is 150° C. or more, the viscosity of the sheet-shaped resin composition 10 decreases, and the unevenness is filled without any gap. If the pasting temperature is 200° C. or less, the sheet-shaped resin composition 10 can be pasted while suppressing the curing reaction thereof.

At this time, if the minimum melt viscosity of the sheet-shaped resin composition 10 is 100 Pa·s to 5,000 Pa·s at less than 200° C., the bump 18 formed on the semiconductor chip 22 and the electrode 52 formed on the substrate 50 for mounting can be made to face each other while easily embedding them into the sheet-shaped resin composition 10.

[Step of Partially Curing Sheet-Shaped Resin Composition]

After the Step C, the sheet-shaped resin composition 10 is semi-cured by heating (Step D). The heating temperature in the Step D is preferably 100° C. to 230° C., and more preferably 150° C. to 210° C. The heating temperature in the Step D is preferably lower than a melting point of the solder. The heating time is preferably 1 second to 300 seconds, and more preferably 3 seconds to 120 seconds.

At this time, if the sheet-shaped resin composition 10 has a thermal curing rate of 10% or more after heating at 200° C. for 10 seconds, the viscosity of the sheet-shaped resin composition 10 after the Step D increases to some extent. As a result, the expansion of voids can be further suppressed.

[Step of Curing Sheet-Shaped Resin Composition While Bonding Bump and Electrode]

As shown in FIG. 4, the sheet-shaped resin composition 10 is cured by being heated at a higher temperature than that in the Step D after the Step D while bonding the bump 18 and the electrode 52 (Step E). FIG. 4 shows that the bump 18 consists of solder and the bump 18 is melted to bond (electrically connect) the bump 18 and the electrode 52.

The heating temperature at this time is preferably 180° C. to 400° C., and more preferably 200° C. to 300° C. The heating time is preferably 1 second to 300 seconds, and more preferably 3 seconds to 120 seconds.

Accordingly, a semiconductor device 60 can be obtained.

According to the method for manufacturing a semiconductor device of the present embodiment, the sheet-shaped resin composition 10 is semi-cured by being heated in a condition in which the chip 40 with sheet-shaped resin composition is pasted onto the substrate 50 for mounting so that the sheet-shaped resin composition 10 becomes a pasting surface (Step D). Therefore, the viscosity of the sheet-shaped resin composition 10 increases before partial curing. Then, the sheet-shaped resin composition is cured by being heated at a higher temperature than that in the Step D (Step E). Because the sheet-shaped resin composition is already semi-cured at a stage of the Step E, the expansion of voids is suppressed even if the voids are caught between the sheet-shaped resin composition 10 and the substrate 50 for mounting. Therefore, the generation of large voids that cause various types of problems can be suppressed.

Next, a specific method for preparing the chip with sheet-shaped resin composition is explained by referring to FIGS. 5 to 11.

The sheet-shaped resin composition of the present embodiment can be integrally used with a tape for grinding the backside or a dicing tape. This makes it possible to manufacture a semiconductor device effectively. FIGS. 5 to 11 are cross sectional views for explaining one example of the method for preparing the chip with sheet-shaped resin composition.

[Sheet-Shaped Resin Composition Integrated with Tape for Grinding Backside]

A sheet-shaped resin composition integrated with a tape for grinding the backside according to the present embodiment has a tape for grinding the backside and the sheet-shaped resin composition.

FIG. 5 is a cross sectional view of a sheet-shaped resin composition 100 integrated with a tape for grinding the backside. As shown in FIG. 5, the sheet-shaped resin composition 100 integrated with a tape for grinding the backside includes a tape 12 for grinding the backside and the sheet-shaped resin composition 10. The tape 12 for grinding the backside includes abase 12a and a pressure-sensitive adhesive layer 12b, and the pressure-sensitive adhesive layer 12b is provided on the base 12a. The sheet-shaped resin composition 10 is provided on the pressure-sensitive adhesive layer 12b.

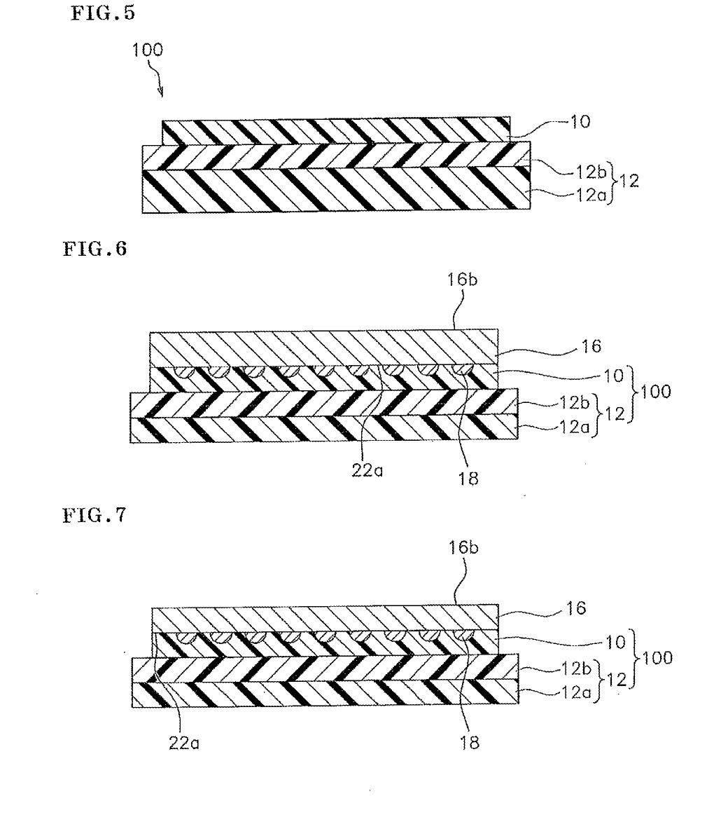

The sheet-shaped resin composition 10 may not be laminated on the entire surface of the tape 12 for grinding the backside as shown in FIG. 5, and it is satisfactory if the sheet-shaped resin composition 10 is provided at a size that is sufficient for pasting with a semiconductor wafer 16 (refer to FIG. 6).

(Tape for Grinding Backside)

The tape 12 for grinding the backside includes the base 12a and the pressure-sensitive adhesive layer 12b that is laminated on the base 12a.

(Base)

A base 12a serves as a strength base of the sheet-shaped resin composition 100 integrated with a tape for grinding the backside. Examples thereof include polyolefin such as low-density polyethylene, straight chain polyethylene, intermediate-density polyethylene, high-density polyethylene, very low-density polyethylene, random copolymer polypropylene, block copolymer polypropylene, homopolypropylene, polybutene, and polymethylpentene; an ethylene-vinylacetate copolymer; an ionomer resin; an ethylene (meth) acrylic acid copolymer; an ethylene (meth) acrylic acid ester copolymer; an ethylene-butene copolymer; an ethylene-hexene copolymer; polyurethane; polyester such as polyethyleneterephthalate and polyethylenenaphthalate; polycarbonate; polyetheretherketone; polyimide; polyetherimide; polyamide; whole aromatic polyamides; polyphenylsulfide; aramid (paper); glass; glass cloth; a fluorine resin; polyvinyl chloride; polyvinylidene chloride; a cellulose resin; a silicone resin; metal (foil); and paper. When the pressure-sensitive adhesive layer 12b is ultraviolet curable, the base 12a is preferably transparent to an ultraviolet ray.

For the base 12a, the same material or different materials can be appropriately selected and used, and one obtained by blending several materials can be used as necessary. A traditional surface treatment can be performed on the surface of the base 12a. The base 12a can be provided thereon with a vapor-deposited layer of an electrically conductive substance made of a metal, an alloy, an oxide thereof, etc., and having a thickness of about 30 Å to 500 Å for imparting an antistatic property. The base 12a may be a single layer or a multi-layer having two or more layers.

The thickness of the base 12a can be appropriately determined, but is generally about 5 μm to 200 μm, and preferably about 35 μm to 120 μm.

The base 12a may contain various kinds of additives (e.g. colorant, filler, plasticizer, antiaging agent, antioxidant, surfactant, flame retardant, etc.).

A pressure-sensitive adhesive used for forming the pressure-sensitive adhesive layer 12b is not particularly limited as long as it can hold a semiconductor wafer at dicing of the backside of a semiconductor wafer and can be peeled from the semiconductor wafer after grinding the backside. For example, a general pressure-sensitive adhesive can be used, such as an acrylic pressure-sensitive adhesive and a rubber pressure-sensitive adhesive. The pressure-sensitive adhesive is preferably an acrylic pressure-sensitive adhesive containing an acrylic polymer as a base polymer in view of clean washing of electronic components such as a semiconductor wafer and glass, which are easily damaged by contamination, with ultrapure water or an organic solvent such as alcohol.

Examples of the acrylic polymer include those using acrylic ester as a main monomer component.

Specific examples of the acrylic ester include an acryl polymer in which acrylate is used as a main monomer component. Examples of the acrylate include alkyl acrylate (for example, a straight chain or branched chain alkyl ester having 1 to 30 carbon atoms, and particularly 4 to 18 carbon atoms in the alkyl group such as methylester, ethylester, propylester, isopropylester, butylester, isobutylester, sec-butylester, t-butylester, pentylester, isopentylester, hexylester, heptylester, octylester, 2-ethylhexylester, isooctylester, nonylester, decylester, isodecylester, undecylester, dodecylester, tridecylester, tetradecylester, hexadecylester, octadecylester, and eicosylester) and cycloalkyl acrylate (for example, cyclopentylester, cyclohexylester, etc.). These monomers may be used alone or two or more types may be used in combination. All of the words including “(meth)” in connection with the present invention have an equivalent meaning.

The acrylic polymer may optionally contain a unit corresponding to a different monomer component copolymerizable with the above-mentioned alkyl ester of (meth)acrylic acid or cycloalkyl ester thereof in order to improve the cohesive force, heat resistance or some other property of the polymer. Examples of such a monomer component include carboxyl-containing monomers such as acrylic acid, methacrylic acid, carboxyethyl (meth)acrylate, carboxypentyl (meth)acrylate, itaconic acid, maleic acid, fumaric acid, and crotonic acid; acid anhydride monomers such as maleic anhydride, and itaconic anhydride; hydroxyl-containing monomers such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth) acrylate, and (4-hydroxylmethylcyclohexyl)methyl(meth)acrylate; sulfonic acid group containing monomers such as styrenesulfonic acid, allylsulfonic acid, 2-(meth)acrylamide-2-methylpropanesulfonic acid, (meth)acrylamidepropanesulfonic acid, sulfopropyl(meth)acrylate, and (meth)acryloyloxynaphthalenesulfonic acid; phosphoric acid group containing monomers such as 2-hydroxyethylacryloyl phosphate; acrylamide; and acrylonitrile. These copolymerizable monomer components maybe used alone or in combination of two or more thereof. The amount of the copolymerizable monomer (s) to be used is preferably 40% or less by weight of all the monomer components.

For crosslinking, the acrylic polymer can also contain multifunctional monomers if necessary as the copolymerizable monomer component. Such multifunctional monomers include hexane diol di(meth)acrylate, (poly)ethylene glycol di(meth)acrylate, (poly)propylene glycol di(meth)acrylate, neopentyl glycol di(meth)acrylate, pentaerythritol di(meth)acrylate, trimethylol propane tri(meth)acrylate, pentaerythritol tri(meth)acrylate, dipentaerythritol hexa(meth)acrylate, epoxy (meth)acrylate, polyester (meth)acrylate, urethane (meth)acrylate etc. These multifunctional monomers can also be used as a mixture of one or more thereof. From the viewpoint of adhesiveness etc., the use amount of the multifunctional monomer is preferably 30 wt % or less based on the whole monomer components.

Preparation of the above acryl polymer can be performed by applying an appropriate manner such as a solution polymerization manner, an emulsion polymerization manner, a bulk polymerization manner, and a suspension polymerization manner to a mixture of one or two or more kinds of component monomers for example. Since the adhesive layer preferably has a composition in which the content of low molecular weight materials is suppressed from the viewpoint of prevention of wafer contamination, and since those in which an acryl polymer having a weight average molecular weight of 300,000 or more, particularly 400,000 to 3,000,000 as a main component are preferable from such a viewpoint, the adhesive can be made to be an appropriate cross-linking type with an internal cross-linking manner, an external cross-linking manner, etc.

To increase the numerical-average molecular weight of the base polymer such as acrylic polymer etc., an external crosslinking agent can be suitably adopted in the pressure-sensitive adhesive. The external crosslinking method is specifically a reaction method that involves adding and reacting a crosslinking agent such as a polyisocyanate compound, epoxy compound, aziridine compound, melamine crosslinking agent, urea resin, anhydrous compound, polyamine, carboxyl group-containing polymer. When the external crosslinking agent is used, the amount of the crosslinking agent to be used is determined suitably depending on balance with the base polymer to be crosslinked and applications thereof as the adhesive. Generally, the crosslinking agent is preferably incorporated in an amount of about 5 parts by weight or less based on 100 parts by weight of the base polymer. The lower limit of the crosslinking agent is preferably 0.1 parts by weight or more. The adhesive may be blended not only with the components described above but also with a wide variety of conventionally known additives such as a tackifier, and aging inhibitor, if necessary.

The pressure-sensitive adhesive layer 12b can be formed by radiation curing-type pressure-sensitive adhesive. By irradiating the radiation curing-type pressure-sensitive adhesive with radiations such as ultraviolet rays, the degree of crosslinking thereof can be increased to easily reduce its adhesive power, so that pickup can be easily performed. Examples of radiations include X-rays, ultraviolet rays, electron rays, a rays, β rays, and neutron rays.

The radiation curing-type pressure-sensitive adhesive having a radiation curing-type functional group such as a carbon-carbon double bond and exhibiting adherability can be used without special limitation. An example of the radiation curing-type pressure-sensitive adhesive is an adding type radiation curing-type pressure-sensitive adhesive in which radiation curing-type monomer and oligomer components are compounded into a general pressure-sensitive adhesive such as an acrylic pressure-sensitive adhesive or a rubber pressure-sensitive adhesive.

Examples of the radiation curing-type monomer component to be compounded include such as an urethane oligomer, urethane(meth)acrylate, trimethylolpropane tri(meth)acrylate, tetramethylolmethane tetra(meth)acrylate, pentaerythritol tri(meth)acrylate, pentaerythritol tetra(meth)acrylate, dipentaerythritol monohydroxypenta(meth)acrylate, dipentaerythritol hexa(meth)acrylate, and 1,4-butane dioldi(meth)acrylate. Further, the radiation curing-type oligomer component includes various types of oligomers such as a urethane based, a polyether based, a polyester based, a polycarbonate based, and a polybutadiene based oligomer, and its weight-average molecular weight is appropriately in a range of about 100 to 30,000. The compounding amount of the radiation curing-type monomer component and the oligomer component can be appropriately determined to an amount in which the adhesive strength of the adhesive layer can be decreased depending on the type of the adhesive layer. Generally, it is for example 5 to 500 parts by weight, and preferably about 40 to 150 parts by weight based on 100 parts by weight of the base polymer such as an acryl polymer constituting the adhesive.

Further, besides the added type radiation curing-type pressure-sensitive adhesive described above, the radiation curing-type pressure-sensitive adhesive includes an internal radiation curing-type pressure-sensitive adhesive using an acryl polymer having a radical reactive carbon-carbon double bond in the polymer side chain, in the main chain, or at the end of the main chain as the base polymer. The internal radiation curing-type pressure-sensitive adhesives of an internally provided type are preferable because they do not have to—and most of them do not—contain the oligomer component, etc., that is, a low molecular weight component, and can form an adhesive layer having a stable layer structure without migration of the oligomer component, etc., in the adhesive over time.

The above-mentioned base polymer, which has a carbon-carbon double bond, may be any polymer that has a carbon-carbon double bond, and further, has viscosity. As such a base polymer, a polymer having an acrylic polymer as a basic skeleton is preferable. Examples of the basic skeleton of the acrylic polymer include the acrylic polymers exemplified above.

The method for introducing a carbon-carbon double bond into any one of the above-mentioned acrylic polymers is not particularly limited, and may be selected from various methods. The introduction of the carbon-carbon double bond into a side chain of the polymer is easier in molecule design. The method is, for example, a method of copolymerizing a monomer having a functional group with an acrylic polymer, and then causing the resultant to condensation-react or addition-react with a compound having a functional group reactive with the above-mentioned functional group and a carbon-carbon double bond while keeping the ultraviolet ray curability of the carbon-carbon double bond.

Examples of the combination of these functional groups include a carboxylic acid group and an epoxy group; a carboxylic acid group and an aziridine group; and a hydroxyl group and an isocyanate group. Of these combinations, the combination of a hydroxyl group and an isocyanate group is preferable from the viewpoint of the ease of reaction tracing. If the above-mentioned acrylic polymer, which has a carbon-carbon double bond, can be produced by the combination of these functional groups, each of the functional groups may be present on any one of the acrylic polymer and the above-mentioned compound. It is preferable for the above-mentioned preferable combination that the acrylic polymer has the hydroxyl group and the above-mentioned compound has the isocyanate group. Examples of the isocyanate compound in this case, which has a carbon-carbon double bond, include methacryloyl isocyanate, 2-methacryloyloxyethyl isocyanate, and m-isopropenyl-α,α-dimethylbenzyl isocyanate. The acrylic polymer used may be an acrylic polymer copolymerized with any one of the hydroxyl-containing monomers exemplified above, or an ether compound such as 2-hydroxyethyl vinyl ether, 4-hydroxybutyl vinyl ether, or diethylene glycol monovinyl ether.

The intrinsic type radiation curing-type pressure-sensitive adhesive may be made only of the above-mentioned base polymer (in particular, the acrylic polymer), which has a carbon-carbon double bond. However, the above-mentioned radiation curing-type monomer component or oligomer component may be incorporated into the base polymer to such an extent that properties of the adhesive are not deteriorated. The amount of the radiation curing-type oligomer component or the like is usually 30 parts or less by weight, preferably from 0 to 10 parts by weight for 100 parts by weight of the base polymer.

In the case that the radiation curing-type pressure-sensitive adhesive is preferably cured with ultraviolet rays or the like, a photopolymerization initiator is incorporated into the adhesive. Examples of the photopolymerization initiator include α-ketol compounds such as 4-(2-hydroxyethoxy)phenyl(2-hydroxy-2-propyl)ketone, α-hydroxy-α,α′-dimethylacetophenone, 2-methyl-2-hydroxypropiophenone, and 1-hydroxycyclohexyl phenyl ketone; acetophenone compounds such as methoxyacetophenone, 2,2-dimethoxy-2-phenylacetophenone, 2,2-diethoxyacetophenone, and 2-methyl-1-[4-(methylthio)-phenyl]-2-morpholinopropane-1; benzoin ether compounds such as benzoin ethyl ether, benzoin isopropyl ether, and anisoin methyl ether; ketal compounds such as benzyl dimethyl ketal; aromatic sulfonyl chloride compounds such as 2-naphthalenesulfonyl chloride; optically active oxime compounds such as 1-phenone-1,1-propanedione-2-(o-ethoxycarbonyl)oxime; benzophenone compounds such as benzophenone, benzoylbenzoic acid, and3,3′-dimethyl-4-methoxybenzophenone; thioxanthone compound such as thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, and 2,4-diisopropylthioxanthone; camphorquinone; halogenated ketones; acylphosphonoxides; and acylphosphonates. The amount of the photopolymerization initiator to be blended is, for example, from about 0.05 to 20 parts by weight for 100 parts by weight of the acrylic polymer or the like which constitutes the adhesive as a base polymer.

When curing hindrance occurs due to oxygen at the time of the irradiation of radiations, it is desirable to block oxygen (air) from the surface of the radiation curing-type pressure-sensitive adhesive layer 12b by some methods. Examples include a method in which the surface of the pressure-sensitive adhesive layer 12b is covered with a separator, and a method in which irradiation of radiations such as ultraviolet rays or the like is carried out in a nitrogen gas atmosphere.

The pressure-sensitive adhesive layer 12b may contain various types of additives (e.g. colorant, thickener, bulking agent, filler, tackifier, plasticizer, antiaging agent, antioxidant, surfactant, cross-linker, etc.).

The thickness of the pressure-sensitive adhesive layer 12b is not particularly limited, but is preferably about 1 μm to 50 μm from the viewpoint of compatibility of prevention of chipping of a chip cut surface, fixation and retention of the sheet-shaped resin composition 10, and so on. The thickness is preferably 2 μm to 30 μm, and more preferably 5 μm to 25 μm.

(Method for Manufacturing Sheet-Shaped Resin Composition Integrated with Tape for Grinding Backside)

For example, the tape 12 for grinding the backside and the sheet-shaped resin composition 10 are separately produced and they are finally pasted onto each other to make the sheet-shaped resin composition 100 integrated with a tape for grinding the backside.

(Method for Preparing Chip with Sheet-Shaped Resin Composition)

Next, a method for preparing the chip with sheet-shaped resin composition will be described. Each of FIGS. 6 to 11 is a view showing each step of the method for preparing the chip 40 with sheet-shaped resin composition using the sheet-shaped resin composition 100 integrated with a tape for grinding the backside.

Specifically, the method for preparing the chip with sheet-shaped resin composition includes: a pasting step of pasting to the sheet-shaped resin composition 10 of the sheet-shaped resin composition 100 integrated with a tape for grinding the backside, the bump formation surface 22a on which the bumps 18 of the semiconductor wafer 16 are formed; a grinding step of grinding a backside 16b of the semiconductor wafer 16; a wafer fixing step of pasting a dicing tape 11 to the backside 16b of the semiconductor wafer 16; a peeling step of peeling the tape 12 for grinding the backside; a dicing step of dicing the semiconductor wafer 16 to form the semiconductor chip 40 with sheet-shaped resin composition; and a pickup step of peeling the semiconductor chip 40 with sheet-shaped resin composition from the dicing tape 11.

<Pasting Step>

In the pasting step, the bump formation surface 22a of the semiconductor wafer 16 on which the bumps 18 are formed is pasted onto the sheet-shaped resin composition 10 of the sheet-shaped resin composition 100 integrated with a tape for grinding the backside (refer to FIG. 6)

A plurality of the bumps 18 are formed on the bump formation surface 22a of the semiconductor wafer 16 (refer to FIG. 6). The height of the bump 18 is determined depending on its use, and it is generally about 15 μm to 100 μm. Naturally, the height of each bump 18 in the semiconductor wafer 16 may be the same as or different from each other.

A height X (μm) of the bump 18 that is formed on the semiconductor wafer 16 and a thickness Y (μm) of the sheet-shaped resin composition 10 preferably satisfy the relationship of 0.5 Y/X≦2. It is more preferably 0.5≦Y/X≦1.5, and further preferably 0.8≦Y/X≦1.3.

When the height X (μm) of the bump 18 and the thickness Y (μm) of the sheet-shaped resin composition 10 satisfy the above relationship, the space between the semiconductor chip 22 and the substrate 50 for mounting can be sufficiently filled, excess flow-out of the sheet-shaped resin composition 10 from the space can be prevented, and contamination, etc., of the semiconductor chip 22 by the sheet-shaped resin composition 10 can be prevented. When the height of each bump 18 is different from each other, the largest height of the bump 18 is set as a standard.

First, a separator is appropriately peeled that is optionally provided on the sheet-shaped resin composition 10 of the sheet-shaped resin composition 100 integrated with a tape for grinding the backside, and the bump formation surface 22a of the semiconductor wafer 16 on which the bumps 18 are formed is arranged to face the sheet-shaped resin composition 10 as shown in FIG. 6, so that the sheet-shaped resin composition 10 and the semiconductor wafer 16 are pasted together (mounting).

The method of the pasting is not particularly limited; however, a method of press-bonding is preferable. The pressure of press-bonding is preferably 0.1 MPa or more, and more preferably 0.2 MPa or more. If the pressure is 0.1 MPa or more, the unevenness of the bump formation surface 22a of the semiconductor wafer 16 can be suitably filled. The upper limit of the pressure of press-bonding is not particularly limited; however, it is preferably 1 MPa or less, and more preferably 0.5 MPa or less.

The temperature at the pasting is preferably 40° C. or higher, and more preferably 60° C. or higher. If the temperature is 40° C. or higher, the viscosity of the sheet-shaped resin composition 10 decreases, and the sheet-shaped resin composition 10 can fill the unevenness of the semiconductor wafer 16 without any gap. The temperature at the pasting is preferably 100° C. or lower, and more preferably 80° C. or lower. If the temperature is 100° C. or lower, the pasting can be performed while suppressing the curing reaction of the sheet-shaped resin composition 10.

The pasting is preferably performed under reduced pressure, for example, 1,000 Pa or less, and more preferably 500 Pa or less. The lower limit is not particularly limited, and for example, 1 Pa or more.

<Grinding Step>

In the grinding step, the surface opposite to the bump formation surface 22a of the semiconductor wafer 16 (that is, the backside 16b) is grinded (refer to FIG. 7). A thin-type processing machine that is used in grinding the backside of the semiconductor wafer 16 is not particularly limited, and examples thereof include a grinding machine (back grinder) and a polishing pas. The backside may be grinded with a chemical method such as etching. The backside is grinded until the thickness of the semiconductor wafer 16 reaches a desired thickness (for example, 10 μm to 800 μm).

<Wafer Fixing Step>

After the grinding step, the dicing tape 11 is pasted onto the backside 16b of the semiconductor wafer 16 (refer to FIG. 8). The dicing tape 11 has a structure in which a pressure-sensitive adhesive layer 11b is laminated on a base 11a. The base 11a and the pressure-sensitive adhesive layer 11b can be suitably produced using the components and the manufacture method shown in the section of the base 12a and the pressure-sensitive adhesive layer 12b for the tape 12 for grinding the backside.

<Peeling Step>

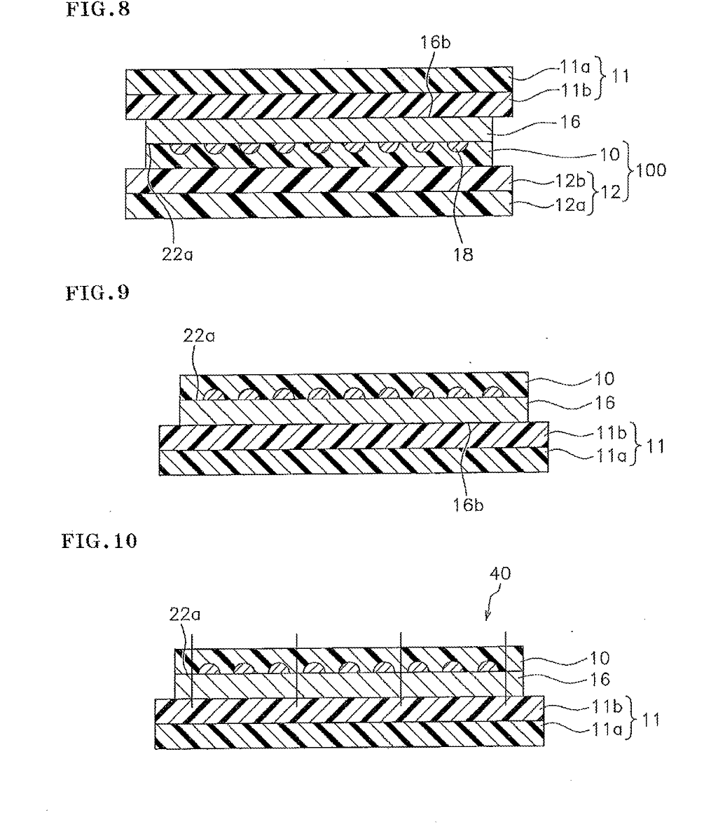

Next, the tape 12 for grinding the backside is peeled (refer to FIG. 9). This allows the sheet-shaped resin composition 10 to be exposed.

When the pressure-sensitive adhesive layer 12b is radiation curable, the pressure-sensitive adhesive layer 12b is cured by irradiating the layer 12b with radiation to easily peel the tape 12 for grinding the backside. The amount of radiation may be appropriately set in consideration of the type of radiation to be used, the degree of curing of the pressure-sensitive adhesive layer, etc.

<Dicing Step>

In the dicing step, the semiconductor wafer 16 and the sheet-shaped resin composition 10 are diced to form the semiconductor chip 40 with sheet-shaped resin composition as shown in FIG. 10. The dicing is performed from the bump formation surface 22a onto which the sheet-shaped resin composition 10 of the semiconductor wafer 16 is pasted with a normal method. An example includes a cutting method called full cut in which cutting is performed up to the dicing tape 11. The dicing apparatus that is used in this step is not particularly limited, and a conventionally known apparatus can be used.

When the expansion of the dicing tape 11 is performed successively after the dicing step, the expansion can be performed by using a conventionally known expanding apparatus.

<Pickup Step>

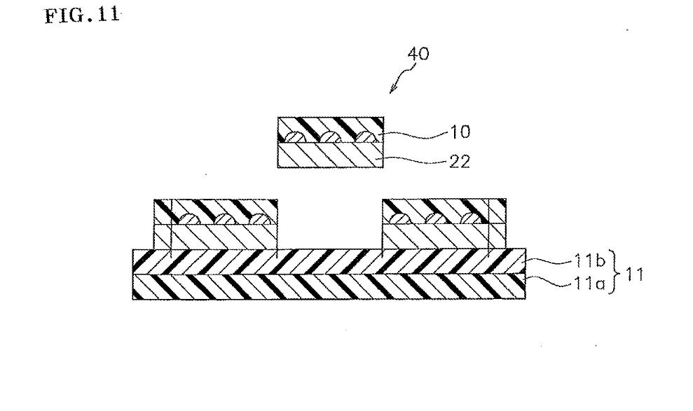

As shown in FIG. 11, the semiconductor chip 40 with sheet-shaped resin composition is peeled from the dicing tape 11 (the semiconductor chip 40 with sheet-shaped resin composition is picked up). The pickup method is not particularly limited, and various types of conventionally known methods can be adopted.

When the pressure-sensitive adhesive layer 11b of the dicing tape 11 is ultraviolet curable, the pickup is performed after irradiating the pressure-sensitive adhesive layer 11b with ultraviolet rays. This allows the adhesive strength of the pressure-sensitive adhesive layer 11b to the semiconductor chip 22 to be decreased, and makes peeling of the semiconductor chip 22 easy.

Accordingly, the preparation of the semiconductor chip 40 with sheet-shaped resin composition is completed.

The method for preparing the semiconductor chip with sheet-shaped resin composition according to the present invention is not limited to the method of using the sheet-shaped resin composition integrated with a tape for grinding the backside.

For example, a sheet-shaped resin composition integrated with a dicing tape maybe used in the preparation. The sheet-shaped resin composition integrated with a dicing tape has a dicing tape and a sheet-shaped resin composition. The dicing tape has a base and a pressure-sensitive adhesive layer, and the pressure-sensitive adhesive layer is provided on the base. The sheet-shaped resin composition is provided on the pressure-sensitive adhesive layer. The configuration of the dicing tape can be adopted that is the same as the above-described tape for grinding the backside.

Specifically, the method for preparing the chip with sheet-shaped resin composition includes: a pasting step of pasting onto the sheet-shaped resin composition of the sheet-shaped resin composition integrated with a dicing tape, the bump formation surface on which the bumps of the semiconductor wafer are formed; a dicing step of dicing the semiconductor wafer to form a semiconductor chip with sheet-shaped resin composition; and a pickup step of peeling the semiconductor chip with sheet-shaped resin composition from the dicing tape.

A single sheet-shaped resin composition may be used in the method for preparing the semiconductor chip with sheet-shaped resin composition.

For example, the method for preparing the chip with sheet-shaped resin composition using a single sheet-shaped resin composition includes: a pasting step of pasting onto the sheet-shaped resin composition, the bump formation surface on which the bumps of the semiconductor wafer are formed; a pasting step of pasting a tape for grinding the backside onto the surface opposite to the pasting surface of the semiconductor wafer; a grinding step of grinding the backside of the semiconductor wafer; a wafer fixing step of pasting a dicing tape to the backside of the semiconductor wafer; a peeling step of peeling the tape for grinding the backside; a dicing step of dicing the semiconductor wafer to form a semiconductor chip with sheet-shaped resin composition; and a pickup step of peeling the semiconductor chip with sheet-shaped resin composition from the dicing tape.

As another example of the method for preparing the chip with sheet-shaped resin composition using a single sheet-shaped resin composition, the method for preparing the chip with sheet-shaped resin composition includes: a pasting step of pasting onto the sheet-shaped resin composition, the bump formation surface on which the bumps of the semiconductor wafer are formed; a pasting step of pasting a dicing tape onto the surface opposite to the pasting surface of the semiconductor wafer; a grinding step of grinding the backside of the semiconductor wafer; a dicing step of dicing the semiconductor wafer to form a semiconductor chip with sheet-shaped resin composition; and a pickup step of peeling the semiconductor chip with sheet-shaped resin composition from the dicing tape.

In the embodiment as mentioned above, the case is described in which electrodes are formed on the substrate for mounting as an adherend when bumps are formed on the semiconductor chip. However, the unevenness (for example, an unevenness of 3 μm or more) caused by bumps, etc., may not be formed on the surface onto which the sheet-shaped resin composition is pasted of the semiconductor chip according to the present invention. Further, the unevenness (for example, an unevenness of 3 μm or more) caused by electrodes, etc. may not be formed on the surface onto which the sheet-shaped resin composition is pasted of the adherend according to the present invention. Even when there is the unevenness of less than 3 m or no unevenness, the voids (for example, fine voids) maybe caught between the sheet-shaped resin composition and the adherend. However, the expansion of voids is suppressed even in these cases because the Step D (step of partially curing the sheet-shaped resin composition by heating) and the Step E (step of heating the sheet-shaped resin composition at a higher temperature than in the Step D to cure the sheet-shaped resin composition after the Step D) are performed. Therefore, the generation of large voids that cause various types of problems can be suppressed also in these cases.

A specific example of the case in which the unevenness is not formed on the surface onto which the sheet-shaped resin composition of the semiconductor wafer is pasted and the unevenness is not formed on the surface onto which the sheet-shaped resin composition of the adherend is pasted includes a case of using the sheet-shaped resin composition as a die bond film.

That is, the method for manufacturing a semiconductor device in this case at least includes: the Step A of preparing a chip with sheet-shaped resin composition in which a sheet-shaped resin composition is pasted onto a semiconductor chip as a die bond film, the Step B of preparing a substrate for mounting such as a lead frame, the Step C of pasting the chip with sheet-shaped resin composition onto the substrate for mounting so that the sheet-shaped resin composition serves as a pasting surface, the Step D of heating the sheet-shaped resin composition to semi-cure the sheet-shaped resin composition after the Step C, and the Step E of heating the sheet-shaped resin composition at a higher temperature than in the Step D to cure the sheet-shaped resin composition after the Step D.

### EXAMPLES

The preferred working examples of this invention will be explained in detail below. However, the materials, the compounding amounts, etc., described in the working examples are not intended to be limited thereto in the scope of this invention unless otherwise specified.

<Production of Sheet-Shaped Resin Composition>

The following components were dissolved in methylethylketone at the proportions shown in Table 1 to prepare a solution of adhesive composition having a solid concentration of 25.4% by weight to 60.6% by weight.

Acrylic polymer: Acrylic acid ester polymer containing ethylacrylate-methylmethacrylate as a main component (trade name “Paracron W-197CM” manufactured by Negami Chemical Industrial Co., Ltd.)

Epoxy resin 1: trade name “Epikote 1004” manufactured by JER Corporation

Epoxy resin 2: trade name “Epikote 828” manufactured by JER Corporation

Phenol resin: trade name “Milex XLC-4L” manufactured by Mitsui Chemicals, Inc.

Inorganic filler: Spherical silica (trade name “SO-25R” manufactured by Admatechs

Thermal curing-accelerating catalyst: Imidazole catalyst (trade name “2PHZ-PW” manufactured by Shikoku Chemicals Corporation)

The solution of the adhesive composition was applied onto a release-treated film of a silicone release-treated polyethylene terephthalate film having a thickness of 50 μm as a release liner (separator), and the resultant was dried at 130° C. for 2 minutes to produce a sheet-shaped resin composition “A” having a thickness of 35 μm.

[Measurement of Minimum Melt Viscosity at Less than 200° C.]

The sheet-shaped resin composition “A” was measured using a rotary viscometer “HAAKE Roto Visco 1” manufactured by Thermo Fisher Scientific. The minimum value of the melt viscosity from 80° C. to 200° C. was considered to be the minimum melt viscosity. The measurement conditions were a rising temperature speed of 10° C/min and a shear rate of 5 (1/s). The result is shown in Table 1.

(Measurement of Thermal Curing Rate after Heating Sheet-Shaped Resin Composition at 200° C. for 10 seconds)

The thermal curing rate was measured using a differential scanning calorimeter, model “Q2000” manufactured by TA Instruments as follows.

First, the heating value (reaction heat of an uncured sample) of a thermally uncured sheet-shaped resin composition “A” was measured when the temperature was increased from −10° C. to 350° C. (a temperature at which the reaction of the uncured sample is assumed to be completed) in a condition of a rising temperature speed of 10° C/min.

Further, a sample was prepared in which the sheet-shaped resin composition “A” was heated at 200° C. for 10 seconds. The heating value of the sample (reaction heat of the uncured sample heated at 200° C. for 10 seconds) was measured when the temperature was increased from −10° C. to 350° C. (a temperature at which the reaction of the uncured sample is assumed to be completed) in a condition of a rising temperature speed of 10° C/min. Then, the thermal curing rate was obtained from the following formula (3).

Thermal curing rate=[{(Reaction heat of uncured sample)−(Reaction heat of sample heated at 200° C. for 10 seconds)}/(Reaction heat of uncured sample)]×100 (%) Formula (3)

The heating value is obtained using an area surrounded by the peak and the straight line connecting two temperature points that are the rising temperature of the exothermic peak measured with a differential scanning calorimeter and the reaction completing temperature.

The result is shown in Table 1.

TABLE 1

| | | |
|---|---|---|
| Compounding | Acrylic Polymer | 100 |
| (parts by | Epoxy Resin 1 | 180 |
| weight) of | Epoxy Resin 2 | 115 |
| Sheet-shaped | Phenol Resin | 300 |
| Resin | Inorganic Filler | 850 |
| Composition | Thermal curing-accelerating catalyst | 45 |
| “A” | Minimum Melt Viscosity (Pa · s) at Less than | 800 |
| | 200° C. | |
| Evaluation | Thermal Curing Rate (%) After Heating at | 13 |
| Results | 200° C. for 10 Seconds | |

(Evaluation of Voids)

The sheet-shaped resin composition “A” having a thickness of 40 μm was pasted onto a test vehicle (test element group in which bumps each having a height of 40 μm are formed on a wafer having a thickness of 725 μm) manufactured by Walts Co., Ltd. The pasting conditions were a temperature of 60° C. and a pasting pressure of 0.5 MPa under a degree of vacuum of 100 Pa. Accordingly, a sample “A” as shown in FIG. 1 was obtained.

### Example 1

Next, a substrate for mounting having electrodes (Height of the electrode: 15 μm) was pasted onto the sample “A”. A flip-chip bonder (FC3000W) manufactured by Toray Engineering Co., Ltd. was used for pasting. The sample “A” was kept at 200° C. for 10 seconds and at 260° C. for 10 seconds in a pasting condition of a load of 0.5 MPa. Then, it was ground parallel to the substrate for mounting, and the vicinity of the bumps on the ground surface was observed.

### Comparative Example 1

In the same manner as Example 1, a substrate for mounting having electrodes (Height of the electrode: 15 μm) was pasted onto the sample “A”. A flip-chip bonder (FC3000W) manufactured by Toray Engineering Co., Ltd. was used for pasting. The sample “A” was kept at 260° C. for 10 seconds in a pasting condition of a load of 0.5 MPa. Then, it was ground parallel to the substrate for mounting, and the vicinity of the bumps on the ground surface was observed.

A case in which the suppression of the generation of voids was observed was determined as ◯, and a case in which the suppression of the generation of voids was observed was determined as ×. The results are shown in Table 2.

TABLE 2

| | | Comparative |
|---|---|---|
| | Example 1 | Example 1 |
| Presence of Step D | Yes | No |
| Evaluation of Voids | ◯ | X |

### REFERENCE CHARACTER LIST

10 Sheet-shaped Resin Composition

18 Bump

22 Semiconductor Chip

22a Bump Formation Surface

40 Chip with Sheet-shaped Resin Composition

50 Substrate for Mounting

52 Electrode

60 Semiconductor Device

1. A method for manufacturing a semiconductor, comprising:
a Step A of preparing a chip with sheet-shaped resin composition in which a sheet-shaped resin composition is pasted onto a semiconductor chip,
a Step B of preparing an adherend,
a Step C of pasting the chip with sheet-shaped resin composition onto the adherend so that the sheet-shaped resin composition serves as a pasting surface,
a Step D of heating the sheet-shaped resin composition to semi-cure the sheet-shaped resin composition after the Step C, and
a Step E of heating the sheet-shaped resin composition at a higher temperature than in the Step D to cure the sheet-shaped resin composition after the Step D.

2. The method for manufacturing a semiconductor device according to claim 1, wherein the sheet-shaped resin composition has a thermal curing rate of 10% or more after heating at 200° C. for 10 seconds.

3. The method for manufacturing a semiconductor device according to claim 1, wherein the adherend has an unevenness of 3 μm to 100 μm on a surface onto which the sheet-shaped resin composition is pasted.

4. The method for manufacturing a semiconductor device according to 1, wherein the semiconductor chip has an unevenness of 3 μm to 100 μm on a surface onto which the sheet-shaped resin composition is pasted.
